(19) United States
(12) Patent Application Publication
(10) Pub. No.: US 2026/0246458 A1
(43) Pub. Date: Aug. 20, 2026

(54) CONTROL CIRCUIT, SEMICONDUCTOR MEMORY DEVICE, AND CONTROL METHOD OF SEMICONDUCTOR MEMORY DEVICE

(71) Applicant: Winbond Electronics Corp., Taichung City (TW)

(72) Inventor: Shinya OKUNO, Yokohama (JP)

(73) Assignee: Winbond Electronics Corp., Taichung City (TW)

(21) Appl. No.: 19/249,793

(22) Filed: Jun. 25, 2025

(30) Foreign Application Priority Data
Feb. 20, 2025 (JP) 2025-025530

(51) Int. Cl. H03K 5/14; G11C 11/4076; H03K 5/00; H03L 7/081

(52) U.S. Cl. CPC H03K 5/14; G11C 11/4076; H03K 2005/0015; H03L 7/0812

(57) ABSTRACT

A control circuit is provided. The control circuit includes a delay section, a detection section, and a control section. The delay section to which a first signal is input has a plurality of delay units coupled in series. Each of the plurality of delay units delays the first signal input thereto. The detection section detects a number of delay units among the plurality of delay units through which the first signal passes when the second signal is input to the detection section after the first signal is input to the delay section. The second signal is a delay signal of the first signal. The control section is configured to control a transmission path of the first signal in the delay section, which causes the number of delay units through which the first signal passes to be equal to the number of delay units detected by the detection section.

### CROSS REFERENCE TO RELATED APPLICATIONS

This Application claims priority of Japan Patent Application No. 2025-025530, filed on Feb. 20, 2025, the entirety of which is incorporated by reference herein.

### BACKGROUND OF THE INVENTION

### Field of the Invention

The present invention relates to a control circuit, a semiconductor memory device, and a control method of the semiconductor memory device.

### Description of the Related Art

A Time-to-Digital Converter (TDC) circuit detects the latency (phase difference) between a first signal and a second signal, and generates a digital value equivalent to this latency. The Time-to-Digital Converter requires each delay element's latency to be designed with high precision. If the latency of each delay element varies or changes due to differences in the process, temperature, or power supply voltage, the Time-to-Digital conversion is affected by PVT (process, voltage, temperature) variations and the desired resolution cannot be obtained. Therefore, how to effectively improve upon the above problems has become a key area of inquiry for Time-to-Digital Converter technology.

### BRIEF SUMMARY OF THE INVENTION

The present invention provides a control circuit, a semiconductor memory device, and a control method thereof. The control circuit includes a plurality of delay units, which causes a portion of the plurality of delay units to generate a digital value corresponding to a specific latency. The latency between a first signal and a second signal is estimated effectively and an output signal corresponding to the latency is generated.

The present invention provides a control circuit. The control circuit includes a delay section, a detection section, and a control section. The delay section to which a first signal is input has a plurality of delay units coupled in series, wherein each of the plurality of delay units delays the first signal input thereto. The detection section detects a number of delay units among the plurality of delay units through which the first signal passes when the second signal is input to the detection section after the first signal is input to the delay section, wherein the second signal is a delay signal of the first signal. The control section is configured to control a transmission path of the first signal in the delay section, which causes the number of delay units through which the first signal passes to be equal to the number of delay units detected by the detection section.

When the second signal is input, the number of delay units through which the first signal passes is the latency between the first signal and the second signal, so that the latency can be easily detected when both the first signal and the second signal are input. In order to make the number of delay units through which the first signal passes equal to the number of delay units detected by the detection section (i.e., the latency between the first signal and the second signal), a transmission path of the first signal is controlled in the delay section, so that the delay section can easily generate an output signal that delays the first signal input thereto. The latency between the first signal and the second signal is effectively estimated, and the output signal corresponding to the latency is generated.

The present invention provides a semiconductor memory device. The semiconductor memory device includes the control circuit as described above.

The present invention provides a control method of a semiconductor memory device. The control method is executed by a control circuit in the semiconductor memory device. The control method includes: detecting a number of the plurality of delay units through which the first signal has passed after a first signal is input to a delay section and when a second signal which is a delayed signal of the first signal is input to the control circuit, wherein the delay section includes a plurality of delay units coupled in series, and each of the plurality of delay units is configured to delay the first signal propagating therethrough; controlling a transmission path of the first signal in the delay section, which causes a number of delay units through which the first signal passes to be equal to the detected number of delay units until the first signal is output from the delay section.

According to the control circuit, the semiconductor memory device, and the control method thereof, the latency between the first signal and the second signal can be effectively estimated, and the output signal corresponding to the latency can be generated.

### BRIEF DESCRIPTION OF THE DRAWINGS

FIG. 1 is a schematic diagram of a semiconductor memory device according to an embodiment of the present invention.

FIG. 2 is a schematic diagram of a control circuit according to an embodiment of the present invention.

FIG. 3 is a timing diagram of the signal voltage change in the control circuit.

FIGS. 4 and 5 are state diagrams of the signal in the control circuit during the latency estimation.

FIG. 6 is a state diagram of the signal in the control circuit during the output signal generation.

FIGS. 7 and 8 are schematic diagrams of a portion of the control circuit in various embodiments.

### DETAILED DESCRIPTION OF THE INVENTION

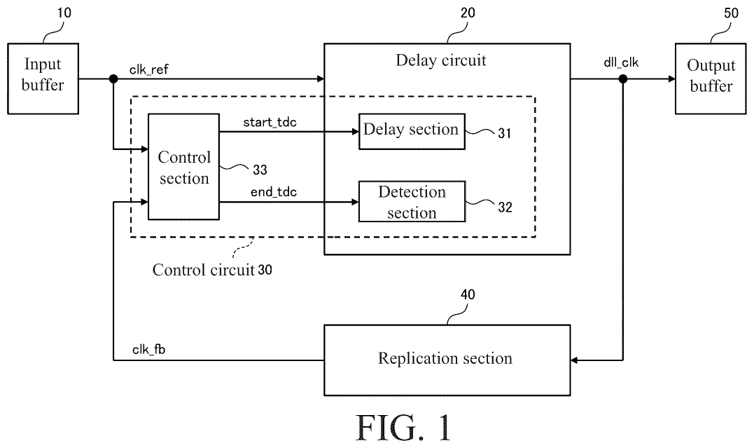

FIG. 1 is a schematic diagram of a semiconductor memory device according to an embodiment of the present invention. As shown in FIG. 1, the semiconductor memory device includes an input buffer 10, a delay circuit 20, a control circuit 30, a replication section 40, and an output buffer 50.

The input buffer 10 receives an external clock signal and buffers it to generate a reference clock signal clk_ref. The reference clock signal clk_ref is output to the delay circuit 20 and the control circuit 30.

The delay circuit 20 is a delay locked loop (DLL) circuit that generates an output clock signal dll_clk by delaying the reference clock signal clk_ref. The delay circuit 20 outputs the output clock signal dll_clk to the replication section 40 and the output buffer 50. The delay circuit 20 has a delay section 31 and a detection section 32 included in the control circuit 30.

The replication section 40 outputs the output clock signal dll_clk generated by the delay circuit 20 to the control circuit 30 as a feedback signal clk_fb.

The output buffer 50 outputs the output clock signal dll_clk generated by the delay circuit 20 as an internal clock signal to other circuits within the semiconductor memory device (omitted in the figure).

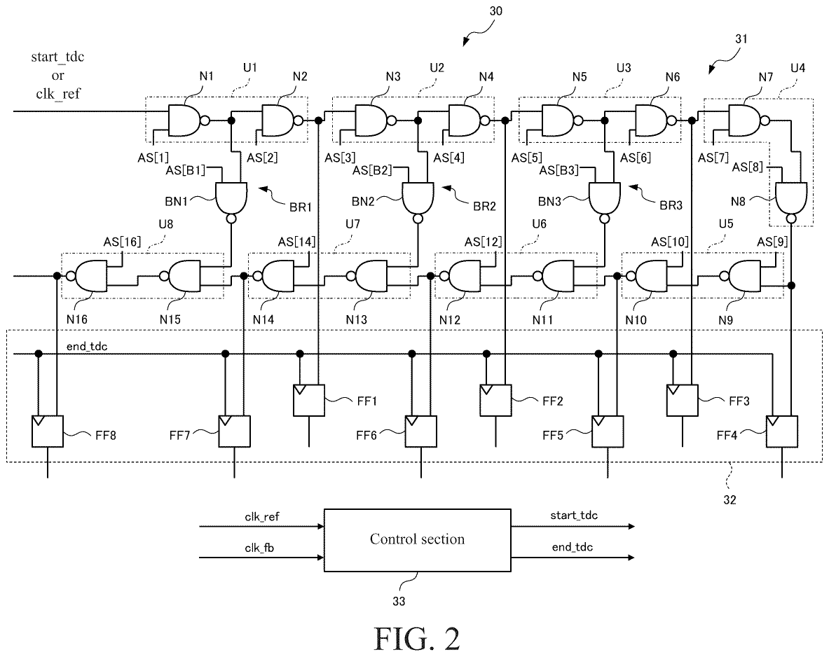

Referring to FIG. 2, the control circuit 30 includes the delay section 31, the detection section 32, and a control section 33.

The delay section 31 enables the input of the reference clock signal clk_ref or a start signal start_tdc, and includes a plurality of delay units U1 to U8 (8 in this embodiment) connected in series. The reference clock signal clk_ref and the start signal start_tdc each represent a “first signal” of the present invention.

The delay units U1 to U8 allow an input signal to be delayed by a certain amount before being output. In FIG. 2, among the delay units U1~U8, a signal (reference clock signal clk_ref or start signal start_tdc) is input to the delay unit U1 at the upstream side of the delay section 31, and the signals output from the delay units U1~U7 previously are input to the delay units U2~U8 subsequently.

The delay units U1~U8 include one or more delay elements for delaying the input signal. Each of the plurality delay units U1~U8 includes an even number (2 in this embodiment) of NAND circuits N1~N16 as one or more delay elements. The logic level of the signal input at the delay section 31 and the logic level of the signals output from each of the delay units U1~U8 are consistent. In addition, in FIG. 2, the delay unit U1 includes two NAND circuits N1, N2. The delay unit U2 includes two NAND circuits N3, N4. The delay unit U3 includes two NAND circuits N5, N6. The delay unit U4 includes two NAND circuits N7, N8. The delay unit U5 includes two NAND circuits N9, N10. The delay unit U6 includes two NAND circuits N11, N12. The delay unit U7 includes two NAND circuits N13, N14. The delay unit U8 includes two NAND circuits N15, N16.

In the NAND circuits N1~N16, the signal (reference clock signal clk_ref or start signal start_tdc) is input to an input terminal of the NAND circuit N1 at the upstream side of the delay section 31, and the signals output from the NAND circuits N1~N15 previously are input to the input terminals of the NAND circuits N2~N16 subsequently. In the NAND circuits N1~N16, the activation signals AS[1]~AS[10], AS[12], AS[14], and AS[16] corresponding to the NAND circuits N1~N10, N12, N14, N16 are input to the other input terminal of each NAND circuit N1~N10, N12, N14, N16. When the logic level of the activation signal AS[i] (i is an integer above 1 and below 16 and excluding 11, 13 and 15) is “1”, the NAND circuit Ni is activated. When the logic level of the activation signal AS[i] is “0”, the NAND circuit Ni is not activatedThe logic level of the activation signal AS[i] is set by the control section 33.

The delay section 31 includes a plurality of bypass paths BR1~BR3 (3 in this embodiment). The input signal (reference clock signal clk_ref or start signal start_tdc) respectively passes through the bypass paths BR1~BR3 with the different numbers of delay units during the period of time until the input signal is output from the delay section 31. In the example of FIG. 2, the bypass path BR1 forms a short between the delay unit U1 and the delay unit U8, so that the number of delay units through which the signal is output from the delay section 31 via the bypass path BR1 is two (delay units U1, U8). In addition, the bypass path BR2 forms a short between the delay unit U2 and the delay unit U7, so that the number of delay units through which the signal is output from the delay section 31 via the bypass path BR2 is 4 (delay units U1, U2, U7, U8). Further, the bypass path BR3 forms a short between the delay unit U3 and the delay unit U6, so that the number of delay units through which the signal is output from the delay section 31 via the bypass path BR3 is 6 (delay units U1, U2, U3, U6, U7, U8).

Each of the plurality bypass paths BR1~BR3 includes at least one delay unit, and is capable of delaying the signal.

In FIG. 2, the bypass path BR1 includes a NAND circuit BN1 as a delay unit, the bypass path BR2 includes a NAND circuit BN2 as a delay unit, and the bypass path BR3 includes a NAND circuit BN3 as a delay unit. An input terminal of the NAND circuit BN1 of the bypass path BR1 is connected to an output terminal of the NAND circuit N1 of the delay unit U1, and an output terminal of the NAND circuit BN1 is connected to the other input terminal of the NAND circuit N15 of the delay unit U8. In addition, an input terminal of the NAND circuit BN2 of the bypass path BR2 is connected to an output terminal of the NAND circuit N3 of the delay unit U2, and an output terminal of the NAND circuit BN2 is connected to the other input terminal of the NAND circuit N13 of the delay unit U7. Further, an input terminal of the NAND circuit BN3 of the bypass path BR3 is connected to an output terminal of the NAND circuit N5 of the delay unit U3, and an output terminal of the NAND circuit BN3 is connected to the other input terminal of the NAND circuit N11 of the delay unit U6. Moreover, the activation signals AS[B1]~AS[B3] are input to the other input terminal of each NAND circuit BN1~BN3 to be activated. The NAND circuit BNj is activated when the logic level of the activation signal AS[Bj] (j is an integer above 1 and below 3) is “1”. The NAND circuit BNj is not activated when the logic level of the activation signal AS[Bj] is “0”, the logic levels of the activation signals AS[B1]~AS[B3] are respectively set by the control section 33.

The delay section 31 is formed in the shape U from the top view (the delay units U1~U8). More specifically, the plurality of NAND circuits N1~N16 are arranged in the shape U from the top view, which allows the areas formed by the delay section 31 to be compactly integrated. In addition, the bypass paths BR1~BR3 are formed by shorting the delay units in the U shape path to shorten the length of the bypass paths BR1~BR3, respectively.

The detection section 32 is formed so that the delay signal (that is, an end signal end_tdc) of the start signal start_tdc can be input. The detection section 32 can detect the number of delay units among the delay units U1~U8 through which the start signal start_tdc passes after the start signal start_tdc is input to the delay section 31 and when the end signal end_tdc is input. The end signal end_tdc is an example of the “second signal” of the present invention.

The detection section 32 includes a plurality of latch sections corresponding to each of the delay units U1~U8. When the end signal end_tdc is input, the signals output from the corresponding delay units U1~U8 are latched in the latch sections. The detection section 32 detects the number of delay units among the delay units U1~U8 when the end signal end_tdc is input, in which the signals with the same value as the start signal start_tdc are latched in the corresponding latch sections as the number of delay units in which the start signal start_tdc passes through the delay units. When the start signal start_tdc and the end signal end_tdc are input separately, the number of delay units that the start signal start_tdc passes through when the end signal end_tdc is input (i.e., the latency between the start signal start_tdc and the end signal end_tdc) can be easily detected.

The latch section includes a flip-flop circuit. The flip-flop circuit includes a D-type flip-flop circuit, which latches the signal output from the delay units U1~U8.

As shown in FIG. 2, the detection section 32 includes D-type flip-flop circuits FF1~FF8 corresponding to each of the delay units U1~U8. The D terminal of the D-type flip-flop circuit FF1 is connected to the output terminal of the NAND circuit N2 of the delay unit U1, and the D terminal of the D-type flip-flop circuit FF2 is connected to the output terminal of the NAND circuit N4 of the delay unit U2. In addition, the D terminal of the D-type flip-flop circuit FF3 is connected to the output terminal of the NAND circuit N6 of the delay unit U3, and the D terminal of the D-type flip-flop circuit FF4 is connected to the output terminal of the NAND circuit N8 of the delay unit U4. The D terminal of the D-type flip-flop circuit FF5 is connected to the output terminal of the NAND circuit N10 of the delay unit U5, and the D terminal of the D-type flip-flop circuit FF6 is connected to the output terminal of the NAND circuit N12 of the delay unit U6. Further, the D terminal of the D-type flip-flop circuit FF7 is connected to the output terminal of the NAND circuit N14 of the delay unit U7, and the D terminal of the D-type flip-flop circuit FF8 is connected to the output terminal of the NAND circuit N16 of the delay unit U8. The end signal end_tdc is input to each of the clock terminals of the D-type flip-flop circuits FF1~FF8, and each of the outputs of the D-type flip-flop circuits FF1~FF8 is sent to the control section 33.

The control section 33 controls the transmission path of the reference clock signal clk_ref in the delay section 31 so that when the reference clock signal clk_ref is output from the delay section 31, the number of delay units that the reference clock signals clk_ref passes through is equal to the number of delay units detected by the detection section 32.

The control section 33 controls the reference clock signal clk_ref to be transmitted through the bypass path (any one of the bypass paths BR1~BR3) formed by the delay section 31. When the reference clock signal clk_ref is output from the delay section 31, the number of delay units through which the reference clock signal clk_ref passes is equal to the number of delay units detected by the detection section 32. The reference clock signal clk_ref is output from the delay section 31 through the bypass path. Therefore, an output signal that delays the number of delay units detected by the detection section 32 can be easily output from the delay section 31.

The control section 33 selects, from among the bypass paths BR1~BR3, a bypass path through which the number of delay units that the reference clock signal clk_ref passes is equal to the number of delay units detected by the detection section 32 when the reference clock signal clk_ref is output from the delay section 31, and controls the transmission of the reference clock signal clk_ref by means of the bypass path. The reference clock signal clk_ref can be delayed by the optimal bypass path selected from among the bypass paths BR1~BR3.

The control section 33 is formed to receive the reference clock signal clk_ref output from the input buffer 10 and the feedback signal clk_fb output from the replication section 40. In addition, the control section 33 sets the start signal start_tdc to be valid (assert, i.e., set a logic level to “1”) at a rising edge of the feedback signal clk_fb and outputs the start signal start_tdc to the delay section 31. Further, the control section 33 sets the end signal end_tdc to be valid (set the logic level to “1”) at the rising edge of the reference clock signal clk_ref after the rising edge of the feedback signal clk_fb and outputs the end signal end_tdc to the detection section 32.

The control section 33 controls the transmission path of the reference clock signal clk_ref in the delay section 31 by setting each logic level of the activation signals AS[1]~AS[10], AS[12], AS[14], and AS[16], and the activation signals AS[B1]~AS[B3] to a value of “1” or “0” according to the number of delay units detected by the detection section 32.

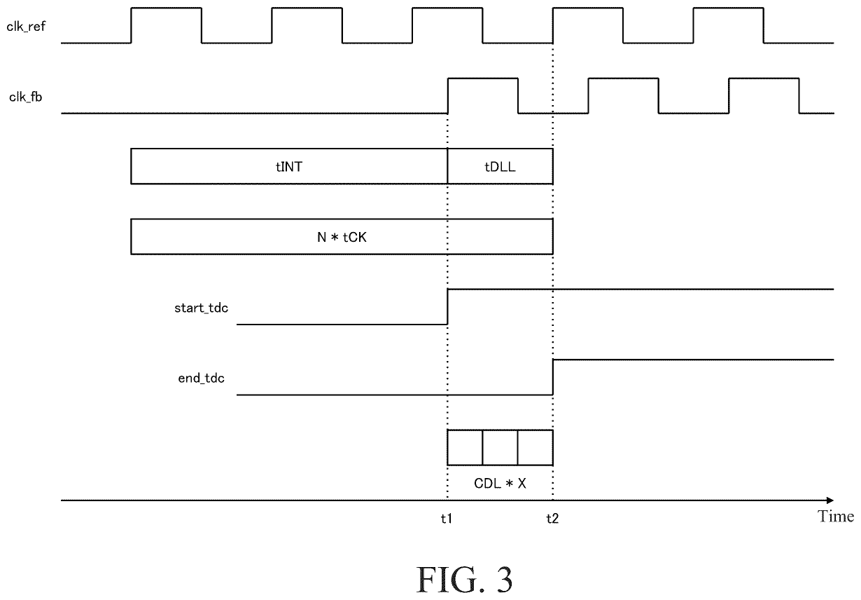

Referring to FIG. 3, the relationship between the signals and the latency in the control circuit 30 is illustrated. When the reference clock signal clk_ref is output from the input buffer 10 and input to the delay circuit 20, the delay circuit 20 delays the reference clock signal clk_ref and generates the output clock signal dll_clk. Assuming that the control circuit 30 does not perform delay detection, the delay circuit 20 generates the output clock signal dll_clk without using the delay section 31. The replication section 40 outputs the output clock signal dll_clk generated by the delay circuit 20 to the control circuit 30 as the feedback signal clk_fb.

Herein, when the DLL circuit is used to adjust the delay of the output clock signal dll_clk, a sequence including a delayed (locked) action of the DLL circuit (e.g., an action that activates the delay lines one by one and synchronizes the reference clock signal clk_ref with the output clock signal dll_clk) is performed.

The locked time tDLL due to the delayed action of the DLL circuit can be expressed by the following equation (1):

$$tINT + tDLL = N \times tCK \qquad equation ( 1 )$$

In addition, the locked time tDLL can be expressed by the following equation (2)

$$tDLL = X \times CDL + Y \times FDL \qquad equation ( 2 )$$

In the above equation (2), the CDL represents the signal latency of a delay unit in a coarse delay line (CDL) with a relatively large adjustment pitch of the latency. The FDL represents the signal latency of the delay unit in a fine delay line (FDL) with a relatively small adjustment pitch of the latency. In addition, X and Y each denote the number of delay units used for signal delay.

As shown in FIG. 3, the period between the rising edge of the feedback signal clk_fb (the corresponding start signal start_tdc) at time t1 and the rising edge of the reference clock signal clk_ref (the corresponding end signal end_tdc) at time t2 is assumed to be almost equal to X×CDL in the above-described equation (2). In the detection section 32, the value of X (i.e., the number of delay units used for signal delay in the CDL (delay section 31)) is detected.

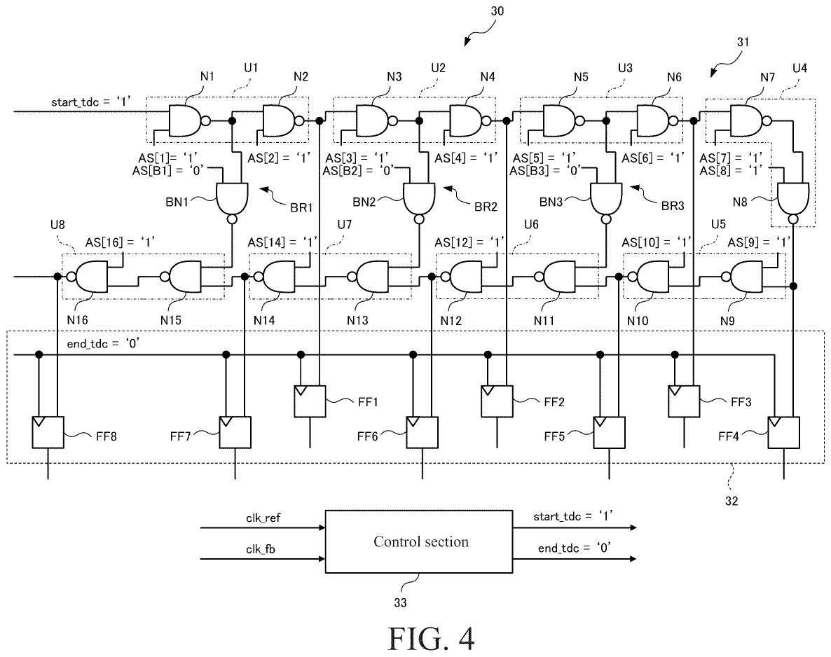

Referring to FIGS. 4 to 6, FIG. 4 illustrates the state of the signal in the control circuit 30 during the latency estimation processing, which shows the logic level of the signal in the control circuit 30 at time t1 of FIG. 3. At time t1, when the rising edge of the feedback signal clk_fb is input to the control section 33, the control section 33 sets the start signal start_tdc to be valid (the logic level is set to “1”) and outputs it to the delay section 31. The control section 33 sets the logic level of each of the activation signals AS[1]~AS[10], AS[12], AS[14], and AS[16] to “1”, and sets the logic level of each of the activation signals AS[B1]~AS[B3] to “0”. Therefore, the start signal start_tdc is transmitted through each delay unit U1~U8 in the delay section 31.

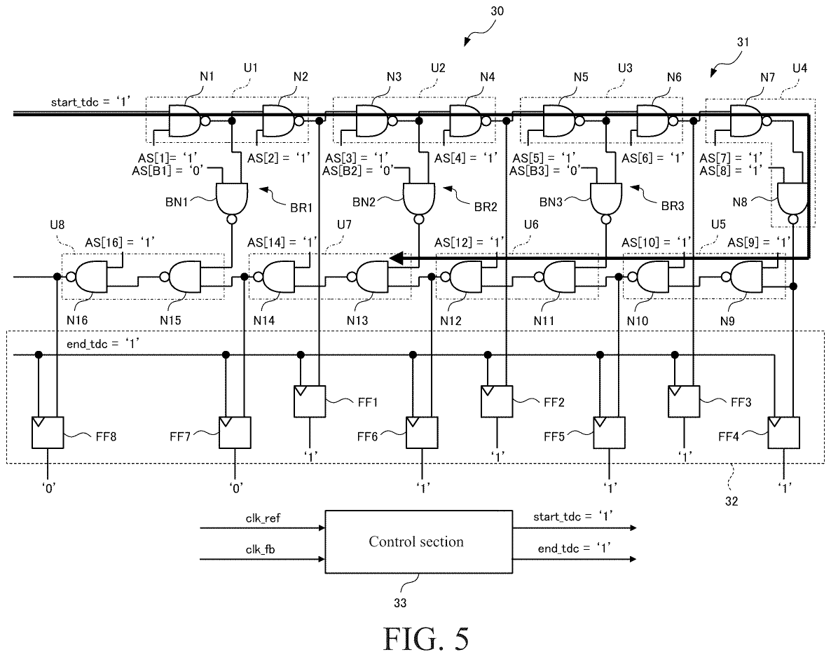

FIG. 5 illustrates the state of the signal in the control circuit 30 during the latency estimation processing, which shows the logic level of the signal in the control circuit 30 at time t2 of FIG. 3. At time t2, when the rising edge of the reference clock signal clk_ref is input to the control section 33 after the rising edge of the feedback signal clk_fb, the control section 33 sets the end signal end_tdc to be valid (the logic level is set to “1”) and outputs it to the detection section 32. Each of the D-type flip-flop circuits FF1~FF8 of the detection section 32 will latch the signals output from the corresponding delay units U1~U8 and output the latched signals to the control section 33. As shown in FIG. 5, at time t2, the valid start signal start_tdc has been transmitted to the delay unit U6, and the logic levels of the signals latched by the D-type flip-flop circuits FF1~FF6 corresponding to each of the delay units U1~U6 are “1”. On the other hand, the start signal start_tdc has not yet been transmitted to the D-type flip-flop circuits FF7~FF8 corresponding to each of the delay units U7~U8, and the logic levels of the signals latched by the D-type flip-flop circuits FF7~FF8 are “0”. Therefore, the detection section 32 can detect (estimate) the number of D-type flip-flop circuits FF1~FF8 that latch a logic “1” signal when the valid end signal end_tdc is input, the number (this number being 6 in the example of FIG. 5) representing the quantity of delay units through which the start signal start_tdc has passed until the input of the valid end signal end_tdc.

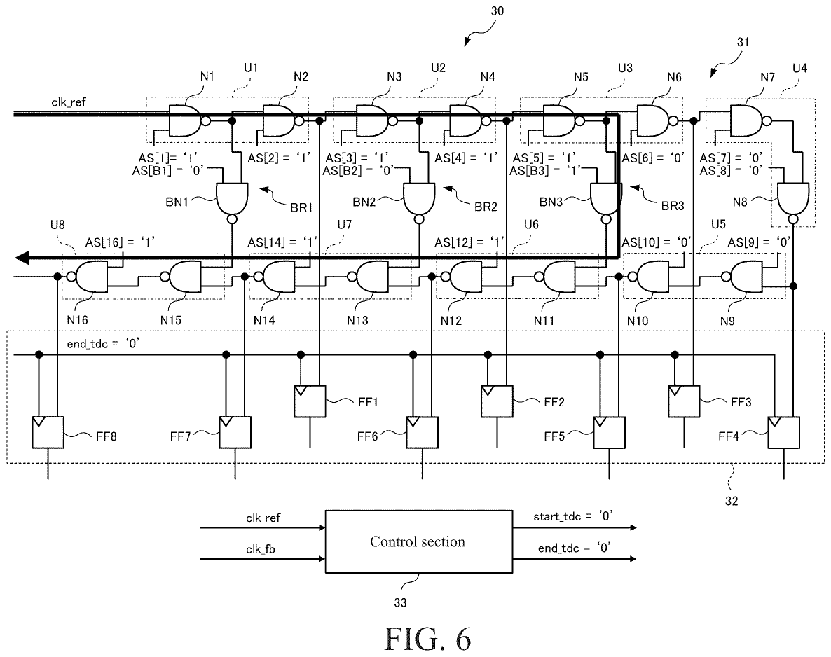

FIG. 6 illustrates the state of the signal in the control circuit 30 during the output signal generation. The control section 33 inputs the reference clock signal clk_ref to the delay section 31 using the switching circuit (omitted in the figure). The control section 33 controls the transmission path of the reference clock signal clk_ref in the delay section 31 in which the number of delay units is equal to the number of delay units detected by the detection section 32 when the reference clock signal clk_ref is output from the delay section 31.

More specifically, the control section 33 controls the transmission path of the reference clock signal clk_ref in the delay section 31 by causing the reference clock signal clk_ref in the delay section 31 to be transmitted through any one of the bypass paths BR1~BR3. The control section 33 sets each of the start signal start_tdc and the end signal end_tdc to be invalid (set the logic level to “0”). As shown in FIG. 6, for example, if the number of delay units detected in the detection section 32 is 6 (the number of NAND circuits is 12), the control section 33 controls the reference clock signal clk_ref to pass through the bypass path BR3 among the bypass paths BR1~BR3, so that the number of delay units through which the reference clock signal clk_ref passes is 6 (the number of NAND circuits is 12) when the reference clock signal clk_ref is output from the delay section 31. The control section 33 sets the logic levels of each of the activation signals AS[1]~AS[5], AS[12], AS[14], AS[16], and AS[B3] to “1”, and sets the logic levels of each of the activation signals AS[6]~AS[10], and AS[B1]~AS[B2] to “0”. Therefore, the reference clock signal clk_ref is transmitted in the delay section 31 through each delay unit U1~U3, the bypass path BR3, and each delay unit U6~U8. That is, the reference clock signal clk_ref is transmitted through the NAND circuits N1, N2, N3, N4, N5, BN3, N11, N12, N13, N14, N15, and N16.

In this case, the delay section 31 easily generates the output signal with the latency detected by the detection section 32 from the input signal (reference clock signal clk_ref).

As described above, according to the control circuit 30, the semiconductor memory device and the control method thereof of the embodiment, when the end signal end_tdc (the second signal) is input, the number of delay units through which the start signal start_tdc (the first signal) passes is detected as the latency between the start signal start_tdc and the end signal end_tdc. The latency can be easily detected by the input of each of the start signal start_tdc and the end signal end_tdc. In addition, according to the control circuit 30, the semiconductor memory device and the control method thereof of the embodiment, the transmission path of the reference clock signal clk_ref in the delay section 31 is controlled in such a manner that the number of delay units through which the reference clock signal clk_ref (the first signal) passes is equal to the number of delay units detected by the detection section 32, so that the delay section 31 can easily generate the output signal with the latency from the input signal (the reference clock signal clk_ref). Therefore, the estimation of the latency between the start signal start_tdc and the end signal end_tdc can be efficiently achieved, and the output signal corresponding to this latency can be generated.

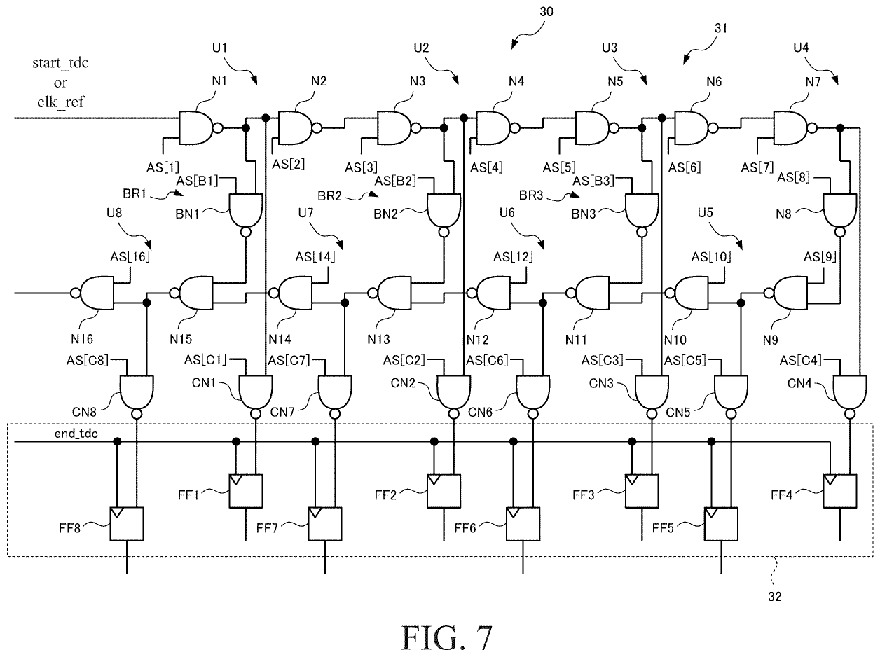

The delay unit Uk (k is an integer above 1 and below 8) includes: the NAND circuit N(2k−1) that delays the start signal start_tdc or the reference clock signal clk_ref (the first signal), and the NAND circuit N(2k) that is coupled to the output of the NAND circuit N(2k−1). As shown in FIG. 7, the delay unit Uk may include the NAND circuit N(2k−1), NAND circuit N(2k), and NAND circuit CNk. The NAND circuit CNk is connected between the NAND circuit N(2k−1) and the corresponding D-type flip-flop circuit FFK (latch section). The NAND circuit N(2k−1) is an example of “first delay element”, the NAND circuit N(2k) is an example of “second delay element”, and the NAND circuit CNk is an example of “third delay element” of the present invention. These three NAND circuits (delay elements) are used to delay the signal.

In FIG. 7, the NAND circuit CN1 is configured between the NAND circuit N1 and the corresponding D-type flip-flop circuit FF1, and the NAND circuit CN2 is configured between the NAND circuit N3 and the corresponding D-type flip-flop circuit FF2. In addition, the NAND circuit CN3 is configured between the NAND circuit N5 and the corresponding D-type flip-flop circuit FF3, and the NAND circuit CN4 is configured between the NAND circuit N7 and the corresponding D-type flip-flop circuit FF4. Further, the NAND circuit CN5 is configured between the NAND circuit N9 and the corresponding D-type flip-flop circuit FF5, and the NAND circuit CN6 is configured between the NAND circuit N11 and the corresponding D-type flip-flop circuit FF6. Furthermore, the NAND circuit CN7 is configured between the NAND circuit N13 and the corresponding D-type flip-flop circuit FF7, and the NAND circuit CN8 is configured between the NAND circuit N15 and the corresponding D-type flip-flop circuit FF8.

In FIG. 7, an input terminal of NAND circuit CN1 is connected to an output terminal of NAND circuit N1, and an output terminal of NAND circuit CN1 is connected to a D terminal of D-type flip-flop circuit FF1. An input terminal of NAND circuit CN2 is connected to an output terminal of NAND circuit N3, and an output terminal of NAND circuit CN2 is connected to a D terminal of D-type flip-flop circuit FF2. An input terminal of NAND circuit CN3 is connected to an output terminal of NAND circuit N5, and an output terminal of NAND circuit CN3 is connected to a D terminal of D-type flip-flop circuit FF3. An input terminal of NAND circuit CN4 is connected to an output terminal of NAND circuit N7, and an output terminal of NAND circuit CN4 is connected to a D terminal of D-type flip-flop circuit FF4. An input terminal of NAND circuit CN5 is connected to an output terminal of NAND circuit N9, and an output terminal of NAND circuit CN5 is connected to a D terminal of D-type flip-flop circuit FF5. An input terminal of NAND circuit CN6 is connected to an output terminal of NAND circuit N11, and an output terminal of NAND circuit CN6 is connected to a D terminal of D-type flip-flop circuit FF6. An input terminal of NAND circuit CN7 is connected to an output terminal of NAND circuit N13, and an output terminal of NAND circuit CN7 is connected to a D terminal of D-type flip-flop circuit FF7. An input terminal of NAND circuit CN8 is connected to an output terminal of NAND circuit N15, and an output terminal of NAND circuit CN8 is connected to a D terminal of D-type flip-flop circuit FF8.

The activation signals AS[C1]~AS[C8] for activating the NAND circuits CN1~CN8 are input to the other input terminal of each of the NAND circuits CN1~CN8. The logic levels of each of the activation signals AS[C1]~AS[C8] can be set by the control section 33. The control section 33 may set the logic levels of each of the activation signals AS[C1]~AS[C8] to “1” (i.e., each of the NAND circuits CN1~CN8 can be activated) during the latency estimation processing described with reference to FIGS. 4 and 5. In addition, the control section 33 can set the logic levels of each of the activation signals AS[C1]~AS[C8] to “0” (i.e., each of the NAND circuits CN1~CN8 can be deactivated) during the output signal generation processing described with reference to FIG. 6.

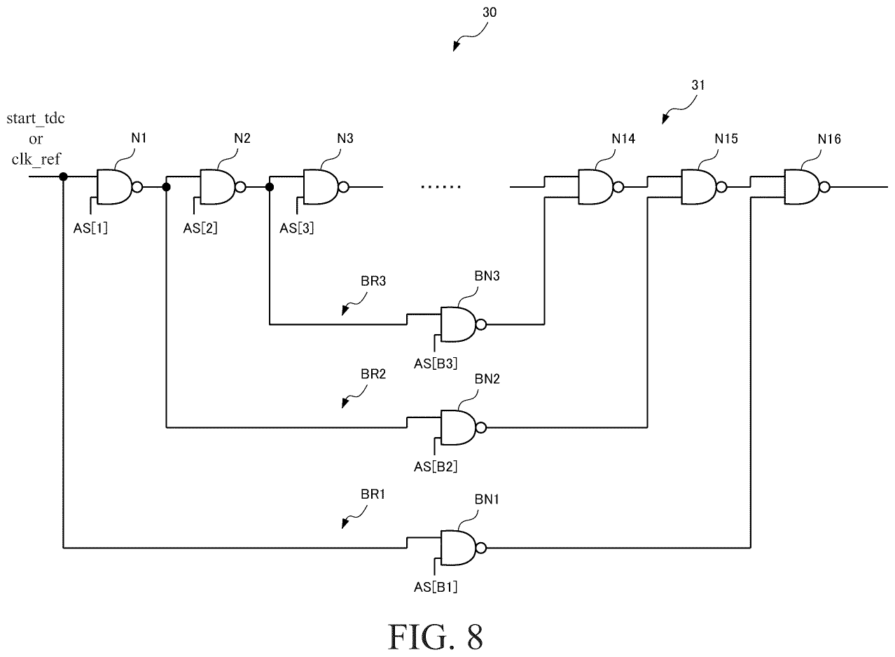

The delay section 31 is in the shape U from the top view, but the present invention is not limited thereto. The delay section 31 may be in a straight line shape as shown in FIG. 8, or have a different shape from the shape U from the top view or the straight line shape.

One delay unit is provided in each bypass path BR1~BR3, and more than two delay units (delay elements) may be provided in at least one of the bypass paths BR1~BR3.

According to the bypass paths BR1~BR3, the number of bypass paths can be set arbitrarily based on the number of delay units through which the input signal passes.

The delay element may be the NAND circuit, but the present invention is not limited thereto. For example, other circuits such as an inverter circuit or a buffer circuit may be used as the delay element.

The semiconductor memory device may be a DRAM, but the present invention is not limited thereto. For example, the semiconductor memory device may be a Static Random Access Memory (SRAM) or pseudo-Static Random Access Memory (pSRAM), flash memory, or other semiconductor memory devices.

What is claimed is:

1. A control circuit, comprising:
a delay section to which a first signal is input, having a plurality of delay units coupled in series, wherein each of the plurality of delay units delays the first signal input thereto;
a detection section to which a second signal is input, wherein a second signal is a delay signal of the first signal, the detection section detects a number of delay units among the plurality of delay units through which the first signal passes when the second signal is input to the detection section after the first signal is input to the delay section; and
a control section, configured to control a transmission path of the first signal in the delay section, which causes the number of delay units through which the first signal passes to be equal to the number of delay units detected by the detection section.

2. The control circuit as claimed in claim 1, wherein the control section controls the first signal to pass through a plurality of bypass paths formed by the delay section for transmission, which causes the number of delay units through which the first signal passes to be equal to the number of delay units detected by the detection section when the first signal is output from the delay section.

3. The control circuit as claimed in claim 2, wherein:
a number of the bypass paths are formed in the delay section, and the number of delay units through which the first signal passes until being output from the delay section differs for each respective bypass path;
a bypass path among the plurality of bypass paths is selected by the control section, which causes the number of delay units through which the first signal passes to be equal to the number of delay units detected by the detection section when the first signal is output from the delay section, and the control section controls the selected bypass path for transmitting the first signal.

4. The control circuit as claimed in claim 2, wherein the plurality of bypass paths comprise at least one delay unit.

5. The control circuit as claimed in claim 1, wherein:
the detection section comprises a plurality of latch sections, and each of the plurality of latch sections corresponds to a respective one of the plurality of delay units, and when the second signal is input, signals output from the corresponding plurality of delay units are latched; and
the detection section is configured to, when the second signal is input, detect a number of the plurality of delay units for which a signal having a value identical to that of the first signal is latched by the corresponding latch section as the number of delay units through which the first signal has passed during the period until the second signal is input.

6. The control circuit as claimed in claim 5, wherein at least one of the plurality of delay units comprises:
a first delay element, configured to delay the first signal;
a second delay element, coupled to an output terminal of the first delay element; and
a third delay element, coupled between the first delay element and its corresponding latch section.

7. The control circuit as claimed in claim 5, wherein the plurality of latch sections comprise flip-flop circuits.

8. The control circuit as claimed in claim 7, wherein the flip-flop circuits comprise D-type flip-flop circuits.

9. The control circuit as claimed in claim 1, wherein the delay section is formed in a shape U from top view.

10. The control circuit as claimed in claim 1, wherein each of the plurality of delay units comprises a plurality of delay elements which delay the first signal.

11. The control circuit as claimed in claim 10, wherein the each of the plurality of delay units comprises an even number of NAND circuits, and the even number of NAND circuits serve as the plurality of delay elements.

12. The control circuit as claimed in claim 11, wherein the each of the plurality of delay units comprises two NAND circuits, and the two NAND circuits serve as the plurality of delay elements.

13. A semiconductor memory device, comprising the control circuit as claimed in claim 1.

14. A control method of a semiconductor memory device, comprising:
detecting, after a first signal is input to a delay section and when a second signal which is a delayed signal of the first signal is input to the control circuit, a number of the plurality of delay units through which the first signal has passed, wherein the delay section comprises a plurality of delay units coupled in series, and each of the plurality of delay units is configured to delay the first signal propagating therethrough;
controlling a transmission path of the first signal in the delay section, which causes a number of delay units through which the first signal passes to be equal to the detected number of delay units until the first signal is output from the delay section.

15. The control method as claimed in claim 14, wherein the control circuit controls the first signal to pass through a plurality of bypass paths formed by the delay section for transmission, which causes the number of delay units through which the first signal passes to be equal to the number of delay units detected by a detection section when the first signal is output from the delay section.

16. The control method as claimed in claim 15, wherein the plurality of bypass paths comprise at least one delay unit.

17. The control method as claimed in claim 14, wherein the delay section is formed in a shape U from top view.

18. The control method as claimed in claim 14, wherein each of the plurality of delay units comprises a plurality of delay elements which delay the first signal.

19. The control method as claimed in claim 18, wherein the each of the plurality of delay units comprises an even number of NAND circuits, and the even number of NAND circuits serve as the plurality of delay elements.

20. The control method as claimed in claim 19, wherein the each of the plurality of delay units comprises two NAND circuits, and the two NAND circuits serve as the plurality of delay elements.
